(19) United States
(12) Patent Application Publication
(10) Pub. No.: US 2006/0170020 A1
(43) Pub. Date: Aug. 3, 2006

(54) Semiconductor memory device and method for fabricating the same

(76) Inventors: Katsuyuki Ohta, Shiga (JP); Takumi Mikawa, Shiga (JP)

Correspondence Address: MCDERMOTT WILL & EMERY LLP, 600 13TH STREET, N.W., WASHINGTON, DC, 20005-3096, US

(21) Appl. No.: 11/198,154

(22) Filed: Aug. 8, 2005

(30) Foreign Application Priority Data
Jan. 28, 2005 (JP) 2005-020542

(51) Int. Cl. H01L 29/94; H01L 21/8242

(52) U.S. Cl. 257/295; 257/E27.086; 257/306; 438/244

(57) ABSTRACT

A semiconductor memory device includes: an insulating layer formed on a semiconductor substrate; a first plug formed inside a first hole formed in the insulating layer; an insulative first hydrogen barrier layer formed on the insulating layer and having a second hole communicating with the first hole; a second plug composed of a conductive second hydrogen barrier layer formed inside the second hole; and a capacitor including a lower electrode, a capacitor insulating layer, and an upper electrode which are formed on the first hydrogen barrier layer and the second plug in this order from bottom to top. A seam is formed in the first plug, and at least one part of the seam is filled with an insulating material.

### CROSS-REFERENCE TO RELATED APPLICATIONS

The disclosure of Japanese Patent Application No. 2005-20542 filed on Jan. 28, 2005 including specification, drawing and claims is incorporated herein by reference in its entirety.

### BACKGROUND OF THE INVENTION

(1) Field of the Invention

The present invention relates to a semiconductor memory device including a ferroelectric or high-dielectric-constant capacitor and a method for fabricating the same.

(2) Description of Related Art

In recent FeRAMs serving as memory devices, a structure has been adopted which prevents plugs of tungsten (W plugs) located below capacitors from being oxidized.

A known semiconductor memory device of the above structure and a fabrication method for the same will be described below with reference to FIGS. 4A through 4C and FIGS. 5A and 5B.

First, as shown in FIG. 4A, a gate electrode 103b is formed in an element formation region of a semiconductor substrate 101 defined by an isolation region 102 thereof with a gate insulating layer 103a interposed therebetween. Thereafter, an impurity diffusion region 104 is formed in the top surface of the semiconductor substrate 101 using the gate electrode 103b as an implantation mask. Subsequently, an insulating layer 105 is deposited on the entire surface of the semiconductor substrate 101 to cover the gate insulating layer 103a and the gate electrode 103b, and then its top surface is planarized by chemical mechanical polishing (CMP). Subsequently, a hole 106 is formed in the insulating layer 105 to reach the impurity diffusion region 104. Then, a material 107a for a barrier metal layer (hereinafter, referred to as “barrier metal layer formation material 107a”) is deposited on the insulating layer 105 and along the sidewall and bottom surfaces of the hole 106. Furthermore, a material 108a for a tungsten layer (hereinafter, referred to as “tungsten layer formation material 108a”) is deposited on the entire surface of the barrier metal layer formation material 107a by blanket chemical vapor deposition (blanket CVD) to fill the inside of the hole 106.

Next, as shown in FIG. 4B, respective parts of the barrier metal layer formation material 107a and the tungsten layer formation material 108a located outside the hole 106 are removed by CMP or an etch-back technique, thereby forming, inside the hole 106, a plug 109 composed of a barrier metal layer 107 and a tungsten layer 108. A recess 110 is formed in a part of the hole 106 located on the plug 109 by etching or other techniques.

Next, as shown in FIG. 4C, a material 11a for a contact metal layer (hereinafter, referred to as “contact metal layer formation material 111a”), such as TiN, is deposited on the insulating layer 105 and inside the recess 110.

Next, as shown in FIG. 5A, a part of the contact metal layer formation material 111a located outside the recess 110 is removed by CMP and an etch-back technique, thereby forming a contact metal layer 111 made of the contact metal layer formation material 111a only inside the recess 110.

Next, as shown in FIG. 5B, a lower electrode 112 is formed on the insulating layer 105 and the contact metal layer 111 to have a multilayer structure of an iridium oxide layer 112a, an iridium layer 112b, an iridium oxide layer 112c, and a Pt layer 112 in bottom-to-top order. Thereafter, a buried insulating layer 113 is formed on the insulating layer 105 to cover the side surface of the lower electrode 112. Subsequently, a ferroelectric layer 114 and an upper electrode 115 are formed, in bottom-to-top order, on the lower electrode 112 and the buried insulating layer 113. The structure of a known semiconductor memory device shown in FIG. 5B is achieved by the above-described known fabrication method for a semiconductor memory device (see Japanese Unexamined Patent Publication No. 2001-284548).

While there are increasing demands for larger capacitance and miniaturization of memory devices, the attendant increased plug aspect ratio may introduce some problems. Specifically, when the aspect ratio of a plug 109 is increased, a seam 116 formed in a tungsten layer 108 with which a hole 106 is filled may be exposed as a large cavity at the top surface of a plug 109 after the formation of a recess 110 in the upper part of the hole 106. After the formation of the recess 110, the step of depositing, on the plug 109, a contact metal layer formation material 111a for a contact metal layer 111 and then the step of depositing, on the contact metal layer 111, a material for a lower electrode 112 (hereinafter, referred to as “lower electrode formation material”) are carried out. Since sputtering is used for these process steps, the contact metal layer formation material 11a or the lower electrode formation material is hardly deposited above the cavity in the seam 116. Therefore, as shown in FIG. 5B, a slit 117 is formed in the contact metal layer 111 and the lower electrode 112. This causes reduction in the oxygen barrier properties. Furthermore, since the slit 117 acts as a path through which hydrogen is diffused into the ferroelectric layer 114, this causes problems, such as deterioration of the ferroelectric layer 114 due to hydrogen. Moreover, when a lower electrode formation material is deposited on the contact metal layer 111, a part of the lower electrode formation material is dropped into the cavity in the seam 116, thereby producing shape abnormalities in the deposited lower electrode formation material. This causes the separation of layers forming the lower electrode 112 having a multilayer structure due to stress at the interfaces between the layers, resulting in contact failure between the contact metal layer 111 and the lower electrode 112.

### SUMMARY OF THE INVENTION

In view of the above, it is an object of the present invention to provide a semiconductor memory device having a structure in which the capacitor characteristics are not deteriorated by a seam formed in a plug electrically connected to a lower electrode forming part of a capacitor using a capacitor insulating layer made of a ferroelectric layer or a high-dielectric-constant layer and a method for fabricating the same.

In order to achieve the above object, a semiconductor memory device of the present invention includes: an insulating layer formed on a semiconductor substrate; a first plug formed inside a first hole formed in the insulating layer; an insulative first hydrogen barrier layer formed on the insulating layer and having a second hole communicating with the first hole; a second plug composed of a conductive second hydrogen barrier layer formed inside the second hole; and a capacitor including a lower electrode, a capacitor insulating layer, and an upper electrode which are formed on the first hydrogen barrier layer and the second plug in this order from bottom to top, wherein a seam is formed in the first plug, and at least one part of the seam is filled with an insulating material.

According to the semiconductor memory device of the present invention, since at least one part of the seam formed inside the first plug is filled with the insulating material, this can prevent a cavity in the seam from being formed at the interface between the first plug and the second plug. Furthermore, since a second hydrogen barrier layer is formed between the first plug and the lower electrode, this eliminates the need for containing a layer having hydrogen barrier properties in the multilayer structure of the lower electrode. Therefore, the number of layers in the multilayer structure of the lower electrode can be decreased, thereby suppressing the separation of the layers due to stress at the interfaces between the layers in the multilayer structure of the lower electrode. As a result, a capacitor can be achieved which is composed of a lower electrode, a capacitor insulating layer and an upper electrode and which has a structure that can prevent the deterioration of the capacitor due to hydrogen and contact failure thereamong.

In the semiconductor memory device of the present invention, the insulating material is preferably identical with a material for the first hydrogen barrier layer.

Thus, at least one part of the seam formed inside the first plug can be filled with the insulating material in the step of forming a first hydrogen barrier layer.

It is preferable that in the semiconductor memory device of the present invention, a barrier metal layer is further formed along the inner wall and bottom of the first hole.

This improves the adhesion between the insulating layer and a material for the first plug and is effective, in particular, when the material for the first plug is tungsten. Furthermore, when the semiconductor substrate is a silicon substrate and the material for the first plug is tungsten, a source gas of tungsten can be prevented from abnormally reacting with silicon at the bottom of the first hole.

In the semiconductor memory device of the present invention, the diameter of the second hole is preferably equal to or larger than the thickness of the first hydrogen barrier layer.

In this case, the aspect ratio of the second hole is low. Therefore, in filling the second hole with a conductive second barrier layer in the formation process of a second plug, the filled second barrier layer can be restrained from being formed to overhang the second hole. This can prevent a seam from being formed inside the second plug.

In the semiconductor memory device of the present invention, the first hydrogen barrier layer is preferably made of silicon nitride.

Thus, the hydrogen barrier properties of the first hydrogen barrier layer can be satisfied.

In order to achieve the above object, a method for fabricating a semiconductor memory device according to an aspect of the present invention includes the steps of: forming an insulating layer on a semiconductor substrate; forming a first hole in the insulating layer; forming a conductive layer on the insulating layer and inside the first hole; removing a part of the conductive layer located outside the first hole to form, inside the first hole, a first plug composed of the conductive layer; forming an insulative first hydrogen barrier layer on the insulating layer and the first plug; forming a second hole in the first hydrogen barrier layer to reach the top surface of the first plug; depositing a conductive second hydrogen barrier layer on the first hydrogen barrier layer and inside the second hole; removing a part of the second hydrogen barrier layer located above the top surface of the first hydrogen barrier layer to expose the top surface of the first hydrogen barrier layer and form a second plug composed of the second hydrogen barrier layer such that the top surface of a part of the second hydrogen barrier layer left inside the second hole is flush with the top surface of the first hydrogen barrier layer or located therebelow; and forming, on the first hydrogen barrier layer and the second plug, a capacitor obtained by stacking a lower electrode, a capacitor insulating layer and an upper electrode in this order from bottom to top.

According to the fabrication method for a semiconductor memory device of the aspect of the present invention, a first hydrogen barrier layer is formed after the formation of a first plug. Therefore, even when a seam is formed inside the first plug, at least one part of the seam can be filled with a material for the first hydrogen barrier layer during the formation of the first hydrogen barrier layer. This can prevent a cavity in the seam from being formed at the interface between the first plug and a second plug. Furthermore, since a second plug formed of a second hydrogen barrier layer is formed between the first plug and a lower electrode, this eliminates the need for containing a layer having hydrogen barrier properties in the multilayer structure of the lower electrode. Therefore, the number of layers in the multilayer structure of the lower electrode can be decreased, thereby suppressing the separation of the layers due to stress at the interfaces between the layers in the multilayer structure of the lower electrode. In view of the above, a capacitor can be achieved which is composed of a lower electrode, a capacitor insulating layer and an upper electrode and has a structure that can prevent the deterioration of the capacitor due to hydrogen and contact failure thereamong.

In the method of the aspect of the present invention, the step of forming the first hydrogen barrier layer preferably includes the step of filling at least one part of a seam formed in the first plug with a material for the first hydrogen barrier layer.

Thus, since at least one part of the seam formed in the first plug is filled with a material for the first hydrogen barrier layer, this can certainly prevent a cavity in the seam from being formed at the interface between the first plug and the second plug.

It is preferable that the method of the aspect of the present invention further includes the step of, after the step of forming the first hole and before the step of forming the first plug, forming a barrier metal layer on the first insulating layer and the inner wall and bottom of the first hole, wherein the step of forming the first plug comprises the step of removing respective parts of the conductive layer and the barrier metal layer located outside the first hole.

This improves the adhesion between the insulating layer and the conductive layer forming the first plug and is effective, in particular, when the conductive layer forming the first plug is tungsten. Furthermore, when the semiconductor substrate is a silicon substrate and the conductive layer forming the first plug is tungsten, a source gas of tungsten can be prevented from abnormally reacting with silicon at the bottom of the first hole.

In the method of the aspect of the present invention, the step of forming the second hole preferably includes the step of forming the second hole such that the diameter of the second hole becomes equal to or larger than the thickness of the first hydrogen barrier layer.

In this case, the aspect ratio of the second hole is low. Therefore, in filling the second hole with a conductive second barrier layer in the formation process of a second plug, the filled second barrier layer can be restrained from being formed to overhang the second hole. This can prevent a seam from being formed inside the second plug.

In the method of the aspect of the present invention, the first hydrogen barrier layer is preferably made of silicon nitride.

Thus, the hydrogen barrier properties of the first hydrogen barrier layer can be satisfied.

As seen from the above, according to the semiconductor memory device and the fabrication method for the same of an aspect of the present invention, a capacitor can be achieved which is composed of a lower electrode, a capacitor insulating layer and an upper electrode and has a structure that can prevent the deterioration of the capacitor due to hydrogen and contact failure thereamong.

### BRIEF DESCRIPTION OF THE DRAWINGS

FIG. 1 is a cross-sectional view showing the structure of the principal part of a semiconductor memory device according to an embodiment of the present invention.

FIGS. 2A through 2C are cross-sectional views showing essential process steps in a method for fabricating a semiconductor memory device according to the embodiment of the present invention.

FIGS. 3A through 3C are cross-sectional views showing the other essential process steps in the method for fabricating a semiconductor memory device according to the embodiment of the present invention.

FIGS. 4A through 4C are cross-sectional views showing essential process steps in a known method for fabricating a semiconductor memory device.

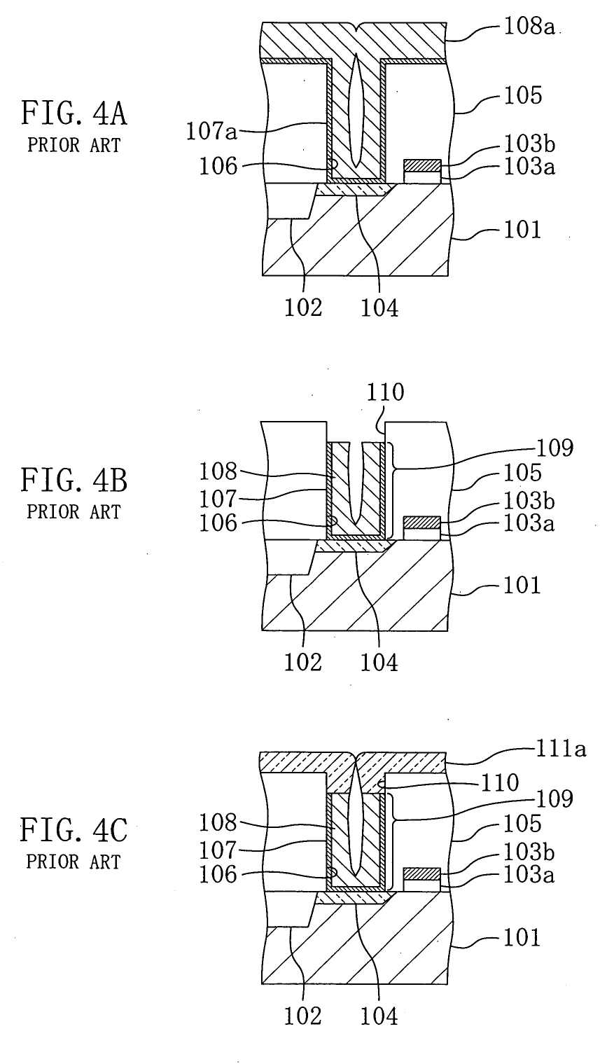

FIGS. 5A and 5B are cross-sectional views showing the other essential process steps in the known method for fabricating a semiconductor memory device.

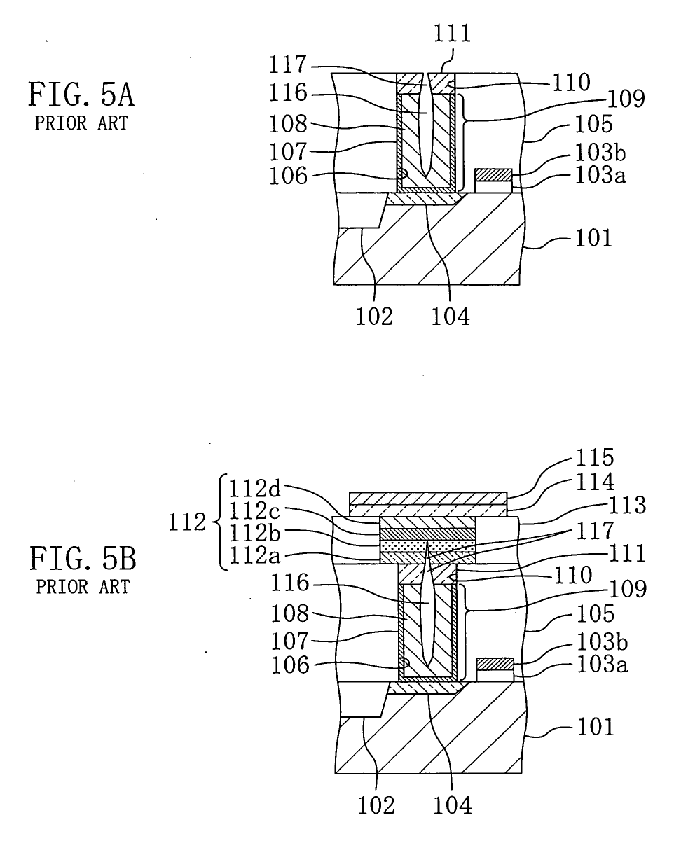

### DETAILED DESCRIPTION OF THE INVENTION

A semiconductor memory device according to an embodiment of the present invention and a method for fabricating the same will be described with reference to the drawings.

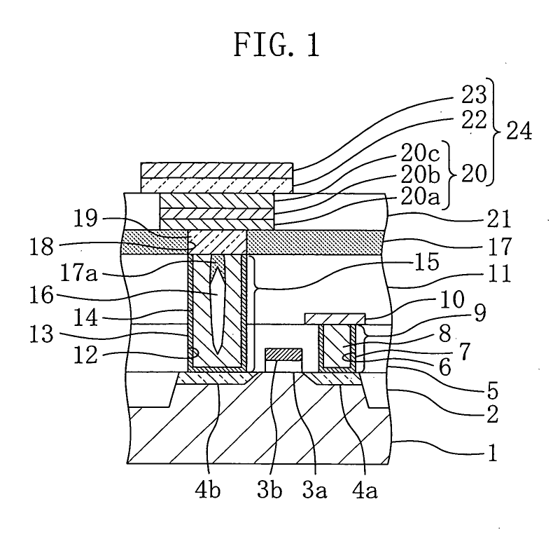

First, the structure of a semiconductor memory device according to the embodiment of the present invention will be described with reference to FIG. 1.

FIG. 1 is a cross-sectional view showing the structure of the principal part of the semiconductor memory device according to the embodiment of the present invention, more particularly, a cross-sectional view showing the structure of a FeRAM cell.

As shown in FIG. 1, a unit memory cell is formed in each element formation region of a semiconductor substrate 1 defined by an isolation region 2 thereof. The unit memory cell includes a gate electrode 3b formed with a gate insulating layer 3a interposed between the semiconductor substrate 1 and the gate electrode 3b and connected to a word line, and impurity diffusion layers 4a and 4b formed in the top surface of the semiconductor substrate 1 such that the gate electrode 3b is interposed therebetween.

A first insulating layer 5 is formed on the entire surface of the semiconductor substrate 1 to cover the gate insulating layer 3a and the gate electrode 3b. A contact hole 6 is formed in the first insulating layer 5 to reach the impurity diffusion layer 4a. A first contact plug 9 is formed in the contact hole 6 such that its lower end is connected to the impurity diffusion layer 4a. The first contact plug 9 is composed of a first barrier metal layer 7 formed along the inner wall and bottom of the contact hole 6 and a first tungsten layer 8 formed to fill the inside of the contact hole 6.

An interconnect layer 10 that will be a bit line and whose lower surface is connected to the top end of the first contact plug 9 is formed on the first insulating layer 5 so as to be connected through the first contact plug 9 to the impurity diffusion layer 4a.

A second insulating layer 11 is formed on the first insulating layer 5 to cover the interconnect layer 10. A first hole 12 is formed in the first and second insulating layers 5 and 11 to reach the impurity diffusion layer 4b. A plug 15 (first plug) composed of a second barrier metal layer 13 formed along the inner wall and bottom of the first hole 12 and a second tungsten layer 14 formed to fill the inside of the first hole 12 is formed in the first hole 12 such that its lower end is connected to the impurity diffusion layer 4b. Furthermore, a seam 16 is formed in the plug 15, and at least one part of the seam 16 is filled with an insulating material 17a (insulator).

An insulative first hydrogen barrier layer 17 is formed on part of the second insulating layer 11. A second hole 18 is formed in the first hydrogen barrier layer 17 to expose the top surface of the plug 15. A second contact plug 19 (second plug) made of a conductive second hydrogen barrier layer is formed in the second hole 18 so as to be connected to the plug 15.

A lower electrode 20 is formed on a part of the first hydrogen barrier layer 17 and the second contact plug 19 so that its lower surface is connected to the top end of the second contact plug 19. A buried insulating layer 21 is formed to come into contact with the side surface of the lower electrode 20. A ferroelectric layer 22 made of strontium bismuth tantalite (SBT) is formed on the lower electrode 20 and part of the buried insulating layer 21, and an upper electrode 23 is formed on the ferroelectric layer 22. In this way, a ferroelectric capacitor 24 composed of the lower electrode 20, the ferroelectric layer 22 and the upper electrode 23 is formed. The ferroelectric capacitor 24 is electrically connected through the plug 15 and the second contact plug 19 to the impurity diffusion layer 4b. The lower electrode 20 has a multilayer structure obtained by stacking an Ir layer 20a, an IrO₂ layer 20b and a Pt layer 20c in bottom-to-top order.

As described above, according to the semiconductor memory device of the embodiment of the present invention, at least one part of the seam 16 formed inside the plug 15 is filled with an insulating material 17a of SiN. This can prevent a cavity in the seam 16 from being formed at the interface between the plug 15 and the second contact plug 19 composed of a second hydrogen barrier layer. Furthermore, since the second contact plug 19 is formed between the plug 15 and the lower electrode 20, this eliminates the need for containing a layer with hydrogen barrier properties in a multilayer structure of the lower electrode 20. The number of layers forming the lower electrode 20 can be decreased, thereby suppressing the separation of the layers due to stress at the interfaces between the layers forming the lower electrode 20. This can prevent deterioration of the ferroelectric capacitor 24 composed of the lower electrode 20, the ferroelectric layer 22 and the upper electrode 23 due to hydrogen or contact failure thereamong.

The insulating material 17a with which at least one part of the seam 16 is filled is made of the same material as that of the first hydrogen barrier layer 17, i.e., SiN. In this way, at least one part of the seam 16 can be filled with the insulating material 17a in the step of forming the first hydrogen barrier layer 17.

Since a second barrier metal layer 13 is formed over the sidewall and bottom of the first hole 12, this improves the adhesion between each of the first and second insulating layers 5 and 11 and the second tungsten layer 14 and can further suppress abnormal reaction between a source gas of tungsten and silicon at the bottom of the first hole 12 during the formation of the second tungsten layer 14.

Since the diameter of the second hole 18 is equal to or larger than the thickness of the first hydrogen barrier layer 17, the aspect ratio of the second hole 18 is low. Therefore, in forming a second contact plug 19 by filling the second hole 18 with a conductive second hydrogen barrier layer, the filled second hydrogen barrier layer can be restrained from being formed inside the second hole 18 to overhang the second hole 18. This can prevent a seam from being formed in the second contact plug 19.

Furthermore, since SiN (silicon nitride) is used as a material for the first hydrogen barrier layer 17, this provides sufficient hydrogen barrier properties of the first hydrogen barrier layer 17.

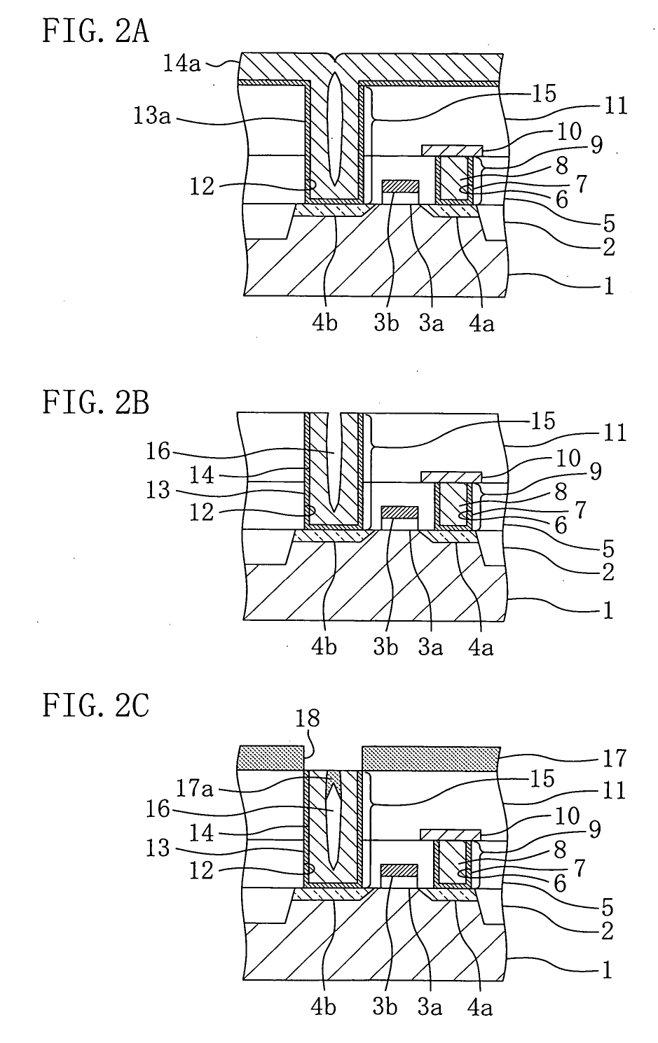

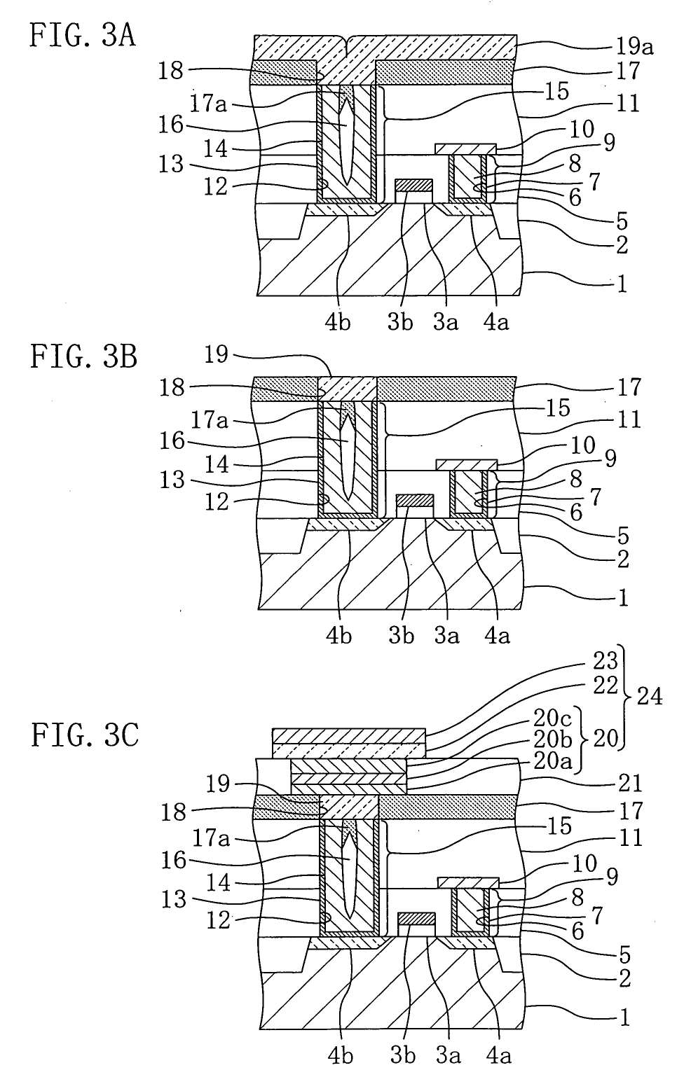

Second, a fabrication method for a semiconductor memory device according to the embodiment of the present invention will be described with reference to FIGS. 2A through 3C.

FIGS. 2A through 3C are cross-sectional views showing essential process steps showing the fabrication method for a semiconductor memory device according to the embodiment of the present invention.

Initially, as shown in FIG. 2A, a gate electrode 3b is formed in an element formation region of a semiconductor substrate 1 defined by an isolation region 2 thereof with a gate insulating layer 3a interposed therebetween. Thereafter, impurity diffusion regions 4a and 4b are formed in the top surface of the semiconductor substrate 1 using the gate electrode 3b as an implantation mask. Subsequently, a first insulating layer 5 of boron phosphorus silicate glass (BPSG) is deposited on the entire surface of the semiconductor substrate 1 to cover the gate insulating layer 3a and the gate electrode 3b, and then its top surface is planarized by CMP.

Subsequently, a mask (not shown) is formed on part of the first insulating layer 5, and then the first insulating layer 5 is subjected to dry etching using the mask. In this way, a contact hole 6 with a diameter of approximately 0.25 μm is formed in the first insulating layer 5 to reach the impurity diffusion region 4a. Next, a material for the later-described first barrier metal layer 7 (hereinafter, referred to as “first barrier metal layer formation material”), having a multilayer structure of a Ti layer (thickness: 10 nm) and a TiN layer (thickness: 40 nm), is deposited, by sputtering, over the sidewall and bottom of the contact hole 6 and the first insulating layer 5. Subsequently, a 200-nm-thick material for a first tungsten layer 8 that will be described below (hereinafter, referred to as “first tungsten layer formation material”) is deposited, by blanket CVD, on the first insulating layer 5 to fill the inside of the contact hole 6. This deposition of the first tungsten layer formation material is executed in an argon atmosphere by blanket CVD in the following manner. First, a nucleation layer is formed to have a thickness of approximately 20 nm (that is the thickness of a part of the nucleation layer located on the first insulating layer 5), under the following conditions: a pressure of 3.66×10³ Pa (30 Torr); a heater temperature of 450° C.; respective flow rates of a WF₆ gas, a SiH₄ gas and a H₂ gas, all serving as a reactive gas, of 4.2×10⁻² ml/min (42 sccm), 5×10⁻³ ml/min (5 sccm) and 5×10⁻¹ ml/min (500 sccm). Then, a first tungsten layer formation material is deposited on the entire surface of the semiconductor substrate 1 to have a thickness of approximately 180 nm (that is the thickness of a part of the first tungsten layer formation material located on the first insulating layer 5), under the following conditions: a pressure of 1.99×10⁴ Pa (90 Torr); a heater temperature of 450° C.; respective flow rates of a WF₆ gas and a H₂ gas both serving as a reactive gas of 1.2×10⁻¹ ml/min (120 sccm) and 5×10⁻¹ ml/min (500 sccm). In this way, space left in the contact hole 6 is filled with the first tungsten layer formation material.

Subsequently, respective parts of the deposited first barrier metal layer formation material and first tungsten layer formation material located outside the contact hole 6 are removed by CMP. Thus, a first barrier metal layer 7 made of the first barrier metal layer formation material and a first tungsten layer 8 made of the first tungsten layer formation material are formed in the contact hole 6. In this way, a first contact plug 9 is formed which is composed of the first barrier metal layer 7 and the first tungsten layer 8.

Next, a conductive layer made of W or the like is deposited on the first insulating layer 5 to have a desired thickness. Thereafter, a mask (not shown) is formed on part of the conductive layer, and the conductive layer is subjected to dry etching using the mask, thereby forming an interconnect layer 10 that will be a bit line so as to be connected to the top end of the first contact plug 9.

Subsequently, a second insulating layer 11 of BPSG or the like is formed on the first insulating layer 5 to cover the interconnect layer 10, and then its top surface is planarized by CMP. Next, a mask (not shown) is formed on part of the second insulating layer 11, and the first insulating layer 5 and the second insulating layer 11 are subjected to dry etching using the mask, thereby forming a first hole 12 in the second insulating layer 11 and the first insulating layer 5 to reach the impurity diffusion region 4b. Next, like the above-mentioned method for depositing a material for a first barrier metal layer 7 and a material for a first tungsten layer 8, a material 13a for a second barrier metal layer (hereinafter, referred to as “second barrier metal layer formation material 13a”) having a multilayer structure of a Ti layer (thickness: 10 nm) and a TiN layer (thickness: 40 nm) is deposited over the sidewall and bottom of the first hole 12 and the second insulating layer 11. Subsequently, a material 14a for a second tungsten layer (hereinafter, referred to as “second tungsten layer formation material 14a”) is deposited on the second insulating layer 11 by blanket CVD to fill the inside of the first hole 12.

Next, as shown in FIG. 2B, respective parts of the deposited second barrier metal layer formation material 13a and second tungsten layer formation material 14a located outside the first hole 12 are removed by CMP. Thus, a plug 15 is formed which is composed of a second barrier metal layer 13 made of the second barrier metal layer formation material 13a and a second tungsten layer 14 made of the second tungsten layer formation material 14a. In this case, the thickness of the TiN layer forming part of a second tungsten layer 13 just after the deposition thereof is set at 40 nm to ensure the hydrogen barrier properties at the bottom of the first hole 12. When a TiN layer is formed by metal organic chemical vapor deposition (MOCVD) using a TDMAT gas or thermal CVD using a TiCl₄ gas and a NH₃ gas as source gases, the TiN layer is formed with excellent coverage. This restrains the TiN layer from overhanging the first hole 12. Therefore, the thickness of the TiN layer just after the deposition thereof can be made thinner. Furthermore, a seam 16 is formed inside the plug 15.

Next, as shown in FIG. 2C, a SiN layer forming an insulative first hydrogen barrier layer 17 that will be described below is deposited on the second insulating layer 11 and the plug 15 by low-pressure CVD to have a thickness of 150 through 230 nm. The thickness of the SiN layer just after the deposition thereof need only be thick enough to ensure the hydrogen barrier properties. When a SiN layer forming the first hydrogen barrier layer 17 is deposited on the second insulating layer 11 and the plug 15, the SiN layer enters into a cavity in the seam 16 existing in the top surface of the plug 15. In this way, the top end part of the seam 16 formed inside the plug 15 is filled with an insulating material 17a of the SiN layer. In this embodiment, a description was given of the case where when the SiN layer forming the first hydrogen barrier layer 17 is deposited on the plug 15 and the second insulating layer 11, the top end part of the seam 16 is filled with the SiN layer. However, even when a SiN layer forming the first hydrogen barrier layer 17 is deposited on the oxide layer after an oxide layer is deposited on the second insulating layer 11 and the plug 15 to have a thickness of several tens through several hundreds of nm in order to reduce stress applied to the multilayer structure, the top end part of the seam 16 can be filled with the oxide layer likewise. Subsequently, a mask (not shown) is formed on part of the SiN layer, and then the SiN layer is subjected to dry etching using the mask, thereby forming, in the SiN layer, a second hole 18 at which the top surface of the plug 15 is exposed. In this way, an insulative first hydrogen barrier layer 17 is formed to have a second hole 18. The diameter of the second hole 18 is set equal to or larger than the thickness of the first hydrogen barrier layer 17.

Next, as shown in FIG. 3A, a TiAlN layer 19a of which an insulative second contact plug 19 that will be described below is made is deposited inside the second hole 18 and on the first hydrogen barrier layer 17 by sputtering.

Next, as shown in FIG. 3B, part of the TiAlN layer 19a located outside the second hole 18 is removed by an etch-back technique or CMP so that part thereof located inside the second hole 18 is left. In this way, a second contact plug 19 is formed such that its top surface is substantially flush with the adjacent top surface of the first hydrogen barrier layer 17 or located slightly below the top surface of the first hydrogen barrier layer 17. Since as described above the second hole 18 has an aspect ratio of about 1 or less than 1, the second hole 18 is completely filled with the TiAlN layer 19a of which the second contact plug 19 is made. This prevents a seam from being formed in the second contact plug 19 formed inside the second hole 18.

Next, as shown in FIG. 3C, an Ir layer 20a, an IrO₂ layer 20b and a Pt layer 20c are deposited on the first hydrogen barrier layer 17 and the second contact plug 19 in bottom-to-top order, and then a mask (not shown) is formed on part of the Pt layer 20c. Thereafter, the Ir layer 20a, the IrO₂ layer 20b and the Pt layer 20c are subjected to dry etching using the mask. Thus, a lower electrode 20 having a multilayer structure is formed such that its bottom surface is connected to the top end of the second contact plug 19. Subsequently, an insulating layer is deposited on the first hydrogen barrier layer 17 to cover the lower electrode 20, for example, by CVD, and then the deposited insulating layer is planarized by CMP to expose the top surface of the lower electrode 20, thereby forming a buried insulating layer 21. Subsequently, a ferroelectric layer 22 made of SBT is formed on the lower electrode 20 and part of the buried insulating layer 21, and then an upper electrode 23 made of Pt is formed on the ferroelectric layer 22. In this way, a ferroelectric capacitor 24 is formed which is composed of the lower electrode 20, the ferroelectric layer 22 and the upper electrode 23.

As described above, in the fabrication method for a semiconductor memory device of the embodiment of the present invention, an insulative first hydrogen barrier layer 17 is formed after the formation of a plug 15. Therefore, even when a seam 16 is formed inside the plug 15, at least one part of the seam 16 can be filled with a material for the first hydrogen barrier layer 17 during the formation of the first hydrogen barrier layer 17. This can prevent a cavity in the seam 16 from being formed at the interface between the plug 15 and a second contact plug 19. This restrains a slit extending along the seam 16 from being formed in the second contact plug 19 located on the plug 15 due to sputtering for the deposition of an insulative TiAlN layer 19a. Furthermore, since a second contact plug 19 formed of the second hydrogen barrier layer 19a is formed between the plug 15 and a lower electrode 20, this eliminates the need for containing a layer having hydrogen barrier properties in the multilayer structure of the lower electrode 20. Therefore, the number of layers in the multilayer structure of the lower electrode 20 can be decreased, thereby suppressing the separation of the layers due to stress at the interfaces between the layers in the multilayer structure of the lower electrode 20. This can prevent the deterioration of a ferroelectric capacitor 24 composed of the lower electrode 20, a ferroelectric layer 22 and an upper electrode 23 due to hydrogen and contact failure thereamong.

An insulating material 17a with which at least one part of the seam 16 is filled is made of the same material as that of the first hydrogen barrier layer 17, i.e., SiN. Therefore, at least one part of the seam 16 can be filled with the insulating material 17a in the step of forming a first hydrogen barrier layer 17.

As described above, the present invention is useful for a memory structure of a semiconductor memory device.

What is claimed is:

1. A semiconductor memory device comprising:
an insulating layer formed on a semiconductor substrate;
a first plug formed inside a first hole formed in the insulating layer;
an insulative first hydrogen barrier layer formed on the insulating layer and having a second hole communicating with the first hole;
a second plug composed of a conductive second hydrogen barrier layer formed inside the second hole; and
a capacitor including a lower electrode, a capacitor insulating layer, and an upper electrode which are formed on the first hydrogen barrier layer and the second plug in this order from bottom to top,
wherein a seam is formed in the first plug, and at least one part of the seam is filled with an insulating material.

2. The device of claim 1, wherein
the insulating material is identical with a material for the first hydrogen barrier layer.

3. The device of claim 1, wherein
a barrier metal layer is further formed along the inner wall and bottom of the first hole.

4. The device of claim 1, wherein
the diameter of the second hole is equal to or larger than the thickness of the first hydrogen barrier layer.

5. The device of claim 1, wherein
the first hydrogen barrier layer is made of silicon nitride.

6. A method for fabricating a semiconductor memory device, the method comprising the steps of:
forming an insulating layer on a semiconductor substrate;
forming a first hole in the insulating layer;
forming a conductive layer on the insulating layer and inside the first hole;
removing a part of the conductive layer located outside the first hole to form, inside the first hole, a first plug composed of the conductive layer;
forming an insulative first hydrogen barrier layer on the insulating layer and the first plug;
forming a second hole in the first hydrogen barrier layer to reach the top surface of the first plug;
depositing a conductive second hydrogen barrier layer on the first hydrogen barrier layer and inside the second hole;
removing a part of the second hydrogen barrier layer located above the top surface of the first hydrogen barrier layer to expose the top surface of the first hydrogen barrier layer and form a second plug composed of the second hydrogen barrier layer such that the top surface of a part of the second hydrogen barrier layer left inside the second hole is flush with the top surface of the first hydrogen barrier layer or located therebelow; and
forming, on the first hydrogen barrier layer and the second plug, a capacitor obtained by stacking a lower electrode, a capacitor insulating layer and an upper electrode in this order from bottom to top.

7. The method of claim 6, wherein
the step of forming the first hydrogen barrier layer comprises the step of filling at least one part of a seam formed in the first plug with a material for the first hydrogen barrier layer.

8. The method of claim 6 further comprising the step of, after the step of forming the first hole and before the step of forming the first plug, forming a barrier metal layer on the first insulating layer and the inner wall and bottom of the first hole,
wherein the step of forming the first plug comprises the step of removing respective parts of the conductive layer and the barrier metal layer located outside the first hole.

9. The method of claim 6, wherein
the step of forming the second hole comprises the step of forming the second hole such that the diameter of the second hole becomes equal to or larger than the thickness of the first hydrogen barrier layer.

10. The method of claim 7, wherein
the first hydrogen barrier layer is made of silicon nitride.
